(19) United States
(12) Patent Application Publication
(10) Pub. No.: US 2013/0270701 A1
(43) Pub. Date: Oct. 17, 2013

(54) SYSTEM AND METHODS FOR WIRE BONDING

(71) Applicants: Randolph Cruz, West Melbourne, FL (US); Nikhil Vishwanath Kelkar, Saratoga, CA (US)

(72) Inventors: Randolph Cruz, West Melbourne, FL (US); Nikhil Vishwanath Kelkar, Saratoga, CA (US)

(73) Assignee: INTERSIL AMERICAS LLC, Milpitas, CA (US)

(21) Appl. No.: 13/539,269

(22) Filed: Jun. 29, 2012

Related U.S. Application Data
(60) Provisional application No. 61/624,764, filed on Apr. 16, 2012.

(51) Int. Cl. H01L 23/49; H01L 21/28

(52) U.S. Cl. 257/738; 438/613; 257/E23.025; 257/E21.158

(57) ABSTRACT

A semiconductor package comprises a bond pad formed on a first semiconductor die, a surface of the bond pad exposed through an opening in a passivation layer on the first semiconductor die; a raised conductive area formed on top of a passivation layer on a second semiconductor die; and a bond wire having a first end coupled to the bond pad via a ball bond and a second end coupled directly to a surface of the raised conductive area via a stitch bond. The raised conductive area is comprised of a plurality of metal layers, each of the metal layers comprised of a respective material and having a respective thickness. The thickness and material of at least one of the plurality of metal layers is selected such that a hardness of the raised conductive area is at least as hard as a hardness of the bond wire.

### CROSS REFERENCE TO RELATED APPLICATIONS

This application claims the benefit under 35 U.S.C. §119(e) of U.S. Provisional Application Ser. No. 61/624,764, filed Apr. 16, 2012, which is incorporated herein by reference in its entirety

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a partial perspective view of one embodiment of an exemplary semiconductor package.

FIG. 2 is an enlarged perspective view of one embodiment of an exemplary raised conductive area.

FIG. 3 depicts a cross section view of one embodiment of a raised conductive area on an exemplary semiconductor die.

FIG. 4 depicts a cross section view of one embodiment of a semiconductor package.

FIG. 5 depicts a cross section view of another embodiment of a raised conductive area on an exemplary semiconductor die.

FIGS. 6A-6J depict one embodiment of process steps in forming one embodiment of a raised conductive area.

FIG. 7A-7J depict one embodiment of process steps for forming an exemplary wire bond interconnect between a bond pad and a raised conductive area.

FIG. 8 is a flow chart of one embodiment of a method of forming a semiconductor package.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual steps may be performed. The following detailed description is, therefore, not to be taken in a limiting sense.

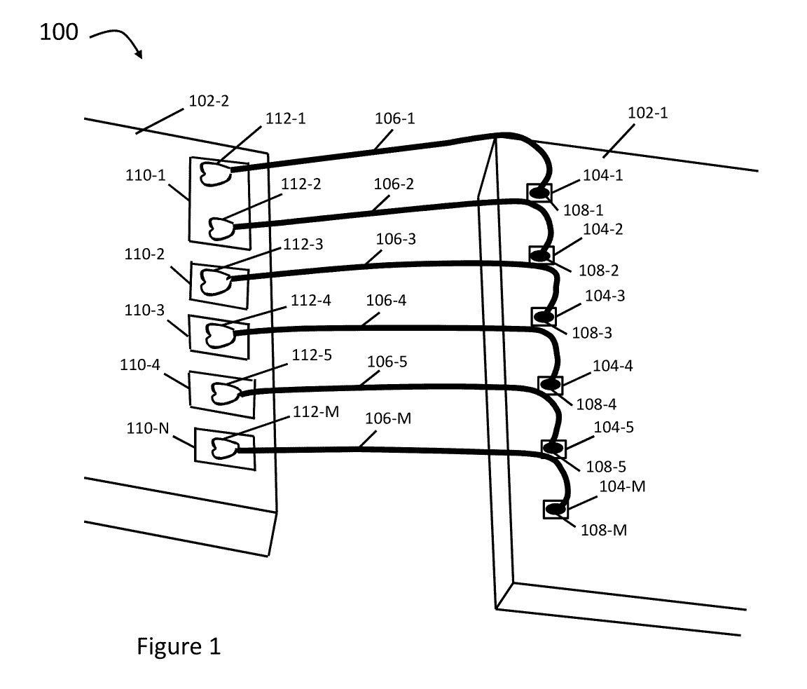

FIG. 1 is a partial perspective view of one embodiment of an exemplary semiconductor package 100. The semiconductor package 100 includes two semiconductor die 102-1 and 102-2. For example, stacked die, multi-chip modules (MCM) or system in package (SiP) are example packaging mechanisms where more than one die are enclosed in the same package in order to save printed circuit board space. However, although two die 102 are shown in this example, it is to be understood that one or more than two die can be used in other embodiments. The semiconductor die 102-1 includes a plurality of bond pads 104-1 . . . 104-M aligned in a column. Although six bond pads 104 are depicted in this example, it is to be understood that any number of bond pads 104 can be used in other embodiments. In addition, the bond pads 104 need not be arranged in a column in other embodiments.

A first end of each of a plurality of corresponding wires 106-1 . . . 106-M is attached to a respective bond pad 104 via a respective ball bond 108. In this embodiment, the wires 106 and the ball bonds 108 are comprised of copper. However, it is to be understood that other conductive materials can be used in other embodiments.

The semiconductor die 102-2 includes a plurality of raised conductive areas 110-1 . . . 110-N. As used herein, the term “raised” refers to being formed above or over top of an uppermost surface or layer of the semiconductor die. For example, in the embodiment of FIG. 1, the raised conductive areas 110 are formed above a passivation layer of the semiconductor die 102-2, as described in more detail below. A second end of each of the wires 106-1 . . . 106-M is attached to a corresponding raised conductive area 110 via a respective stitch bond 112. Stitch bonding is a technique where a bonder head feeds a wire, such as a copper wire in this example, to a conductive surface. The bonder head then applies energy and pressure to “stitch” the wire to the conductive surface, forming what-looks like a tail. The stitch bond footprint is also sometimes known as a fish-tail bond or a short-tail bond.

Notably, the wires 106 are stitch bonded directly to a surface of the raised conductive areas 110 rather than forming a ball bond or other separation between the stitch bond and raised conductive areas 110. The configuration of the raised conductive areas 110, as discussed in more detail below, enables the direct stitch bonding of the wires 106 to the raised conductive areas 110 without damaging the structures of the underlying semiconductor die 102-2. In addition, the configuration of the raised conductive areas enables the use of copper wire having a diameter larger than 0.9 mil while still protecting underlying circuitry. For example, in one embodiment, a copper wire having a diameter of 1.3 mil is used for the bondwires 106.

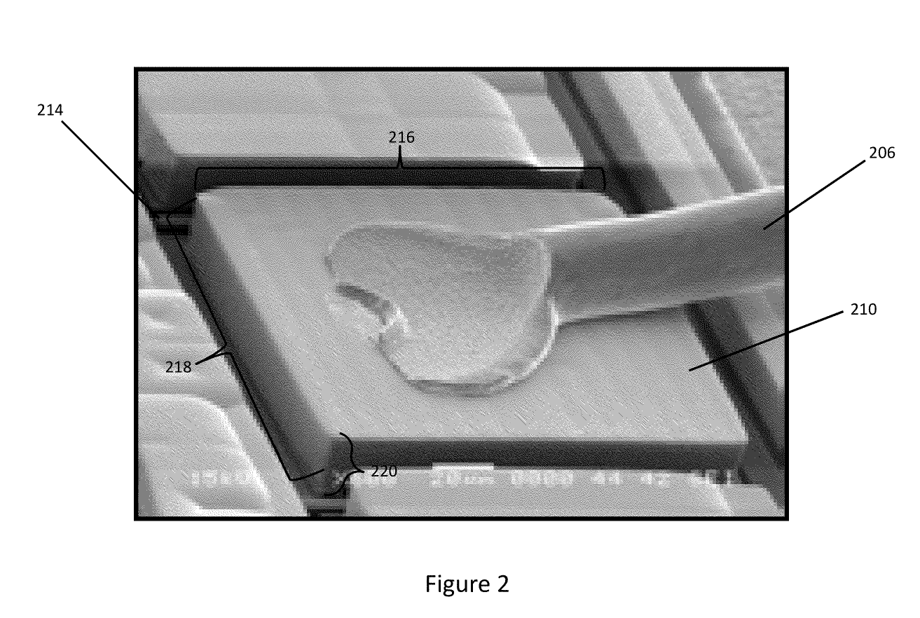

An enlarged perspective view of an exemplary raised conductive area 210 is shown in FIG. 2. As can be seen the wire 206 is stitch bonded directly to a surface of the raised conductive area 210. The raised conductive area 210 is formed above the passivation layer 214 on the semiconductor die. In addition, the raised conductive area 210 has a width 216 and a length 218. The width 216 and length 218 are configured to form a conductive area sufficiently large to accommodate the stitch bond process and resulting footprint while also preventing the bonder head from contacting the structures of the semiconductor die. For example, in some embodiments, each of the width 216 and the length 218 are 20-30% larger than the diameter of the wire 206. However, it is to be understood that the width 216 and length 218 are not to be so limited and can vary in other embodiments. For example, in the embodiment of FIG. 1, the raised conductive area 110-1 has a width and length configured to accommodate two stitch bonds. Thus, in some embodiments, a plurality of stitch bonds can be made to the surface of the same raised conductive area. Stitch bonding a plurality of wires to the same raised conductive area can aid in accommodating high currents and/or achieving lower resistance. Additionally, in other embodiments, the width 216 and length 218 can be reduced to the size needed to place the stitch bond. By limiting the size to the area needed to place the stitch bond, fine pitch application (e.g. high density) are enabled.

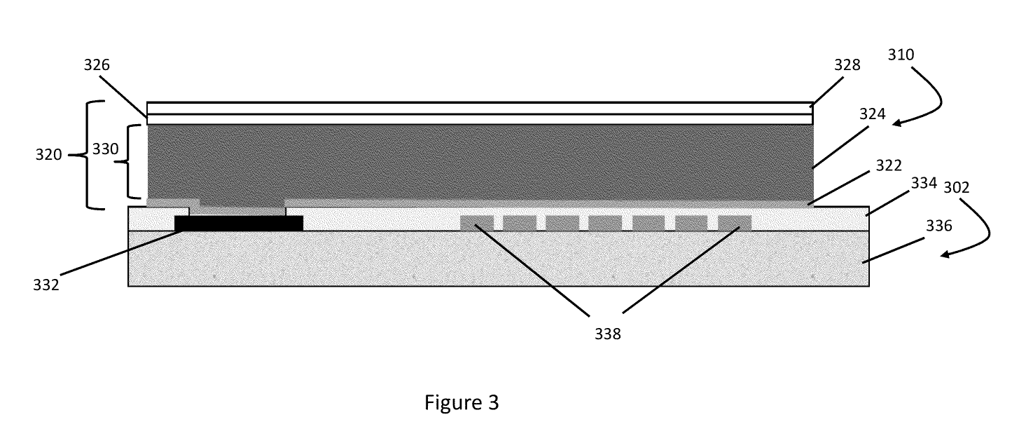

The thickness 220 of the raised conductive area 210 and the material composition of the raised conductive area 210 are selected such that the hardness of the raised conductive area 210 is approximately the same as or greater than the hardness of the wire 206. For example, FIG. 3 depicts a cross section view of one embodiment of a raised conductive area 310 on an exemplary semiconductor die 302 which depicts the thickness of the raised conductive area 310.

The raised conductive area 310 comprises a plurality of metal layers 322, 324, 326, and 328. Metal layer 322 is a seed layer and can be comprised of any of various metals known for use as a seed metal layer. For example, in this embodiment, the seed metal layer 322 is comprised of Titanium Tungsten (TiW). The metal layer 324 has a thickness 320 that is relatively thicker than the other metal layers of the raised conductive area 310. In addition, the metal layer 324 is comprised of a material that when combined with the thickness 330 results in a hardness approximately equal to or greater than the hardness of a bondwire to be attached to the raised conductive area 310. In some embodiments, when the bondwire material is similar to the material of the metal layer 324, the thickness 330 of the metal layer 324 is approximately equal to the diameter of the bond wire. For example, in one embodiment, both the bondwire and the metal layer 324 are comprised of copper (Cu) and have a respective diameter or thickness of approximately 20 μm. Thus, the metal layer 324 in such an embodiment is configured for stitch bonding of a copper bondwire to the raised conductive area 310. It is to be understood that the thickness of the metal layer 324 and the material of the metal layer 324 can be different in other embodiments and is not limited to exemplary values described herein. Furthermore, it is to be understood that the thickness of metal layer 324 need not be equal to the diameter of the bondwire, even in some embodiments in which the metal layer 324 and the bondwire are comprised of the same material, so long as the hardness of the raised conductive area is approximately equal to or greater than the hardness of the bondwire.

The metal layer 324 is plated with metal layers 326 and 328 to provide an approximately oxide-free planar surface which improves the ability to bond a bondwire to the surface of metal layer 328. For example, in one embodiment, the metal layer 326 is comprised of Nickel (Ni) and the metal layer 328 is comprised of gold (Au). However, it is to be understood that other metals and metal alloys, such as silver or gold palladium, can be used in other embodiments for metal layers 326 and 328. In this embodiment, the metal layer 326 is approximately 2 μm thick and the metal layer 328 is approximately 0.5 μm thick.

The raised conductive area 310 is coupled to a bond pad 332, such as an Aluminum (Al) bond pad, in the semiconductor die 302. In particular, an opening in the passivation layer 334 exposes the bond pad 332 and enables coupling of the raised conductive area 310 to the bond pad 332. The exemplary semiconductor die 302 in this example also includes a substrate 336 and circuits or devices 338 formed on the substrate 336. It is to be understood that the semiconductor die 302 is simplified for purposes of explanation and that the semiconductor die can include other components, such as one or more metal layers, insulating layers, interconnects, vias, etc., in other embodiments. In addition, as shown in FIG. 3, the hardness of the conductive area 310 enables circuits 338 to be placed under a portion of the conductive area 310 without being damaged during the bondwire attachment process.

In particular, the raised conductive area 310 provides a separation between the capillary head used to form the stitch bond which reduces the likelihood that the capillary head contacts and scrapes/damages the semiconductor die. In addition, the size and hardness of the raised conductive area 310 act as a buffer to further reduce the likelihood that the pressure applied by the capillary head will produce cratering and cracking of an inter-layer dielectric (ILD) underneath the raised conductive area 310. This in turn also reduces the likelihood of damage to any circuitry underneath the raised conductive area 310.

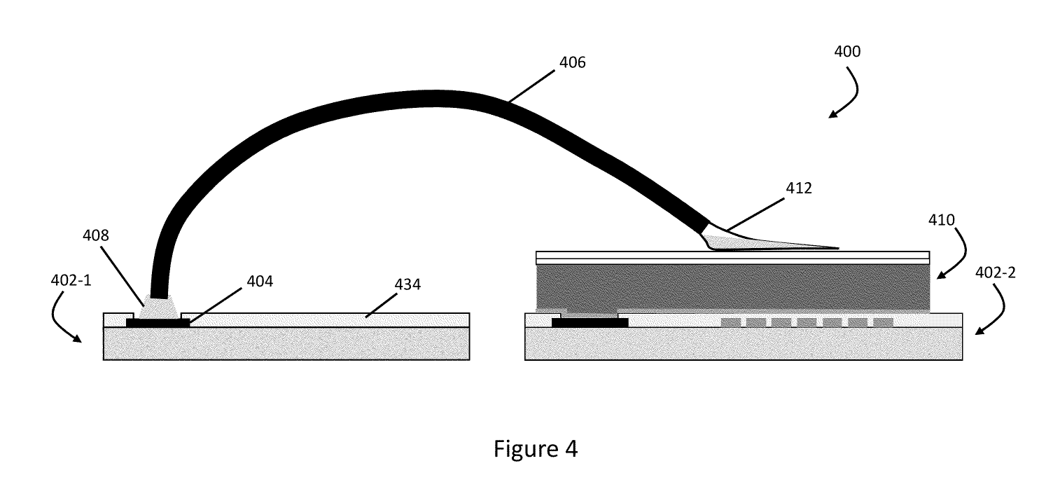

FIG. 4 depicts a cross section view of one embodiment of a semiconductor package 400. In particular, semiconductor package 400 includes die 402-1 having a bond pad 404 similar to die 102-1 in FIG. 1. Similar to package 100 in FIG. 1, one end of a bondwire 406 is bonded to the bondpad 404 through an opening a passivation layer 434 via a ball bond 408. The other end of the bondwire 406 is bonded to the surface of raised conductive area 410 on a semiconductor die 402-2 via a stitch bond 412. The raised conductive area 410 is similar to the raised conductive area 310 discussed in FIG. 3. Although two die 402 are shown in FIG. 4, it is to be understood that a single die can be used in other embodiments. In particular, both the bond pad 404 and the raised conductive area 410 can be located in the same die in other embodiments.

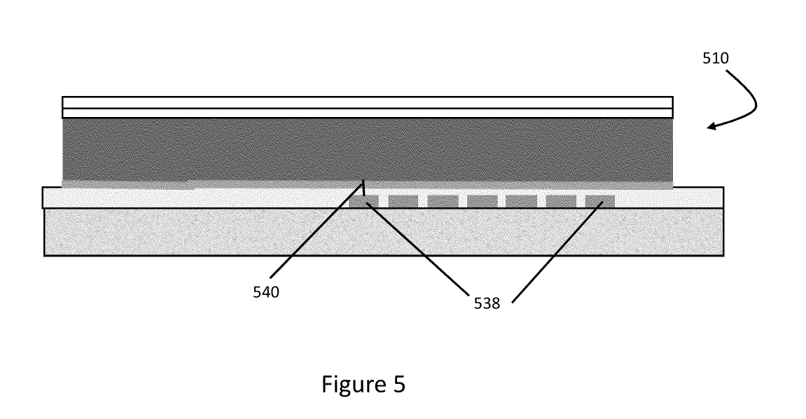

In addition, although the raised conductive area 410 is coupled to a bond pad 432 in this example, the raised conductive area 410 is not coupled to a bond pad 432 in other embodiments. For example, as shown in FIG. 5, the raised conductive area 510 is coupled to circuitry 538 through the use of vias 540 rather than a bond pad. Thus, the raised conductive area 510 can be used as a routable interconnect pad. In addition, it is to be understood that the actual connection to the chip circuitry 538 can located at a different location than raised conductive area 510. For example, the circuitry 538 need not be located directly under the raised conductive area 510 and can be electrically coupled to the raised conductive area 510 via traces.

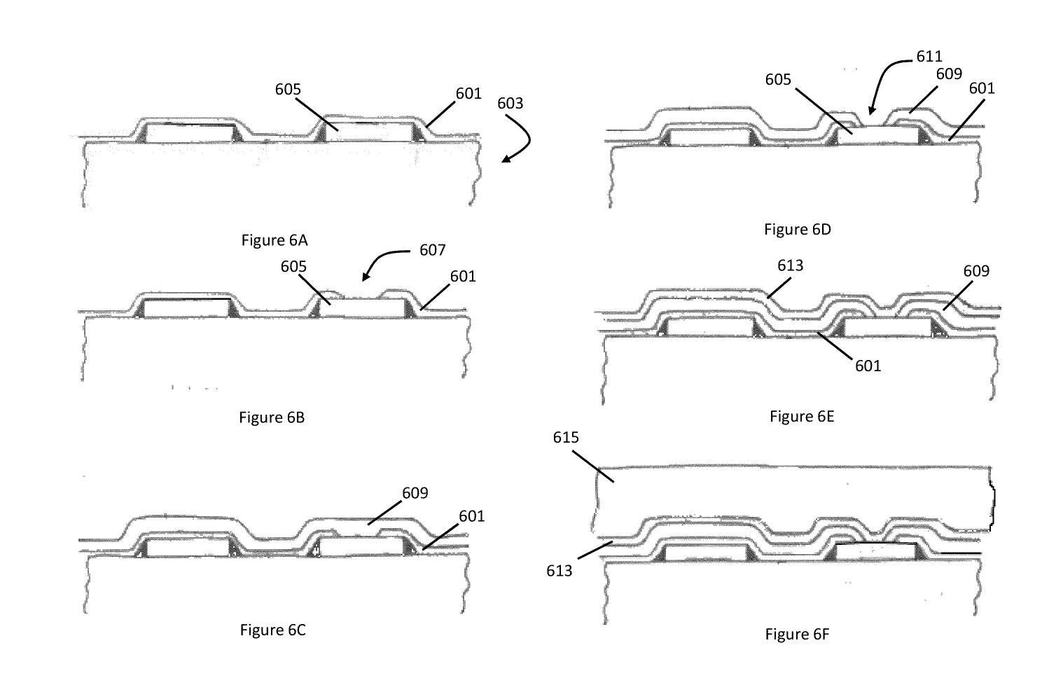

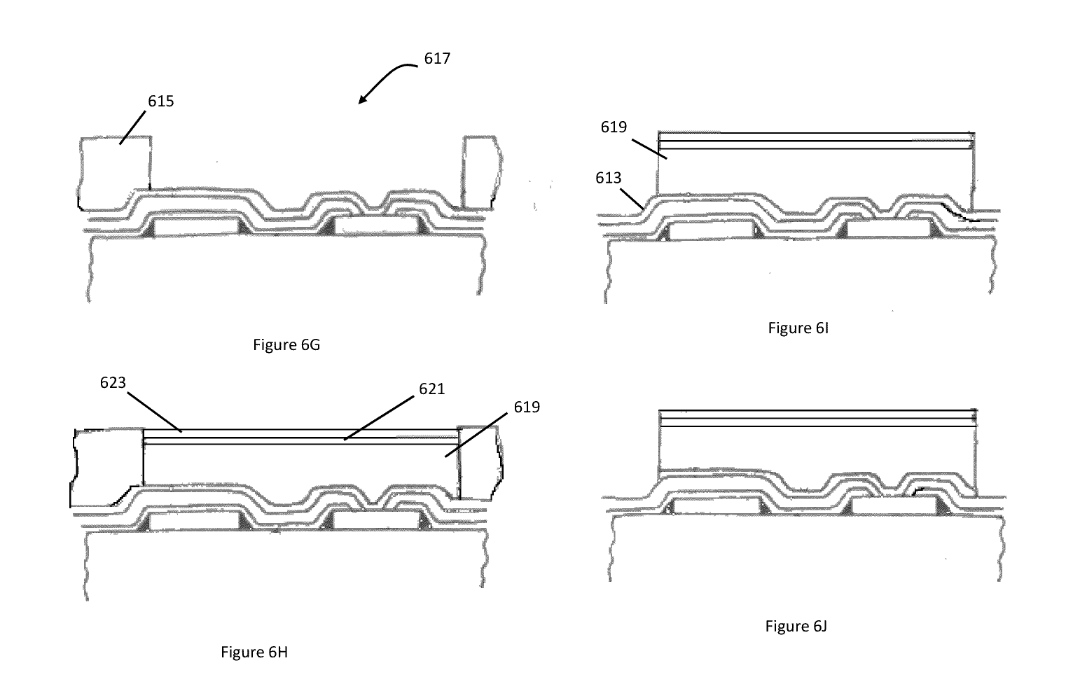

FIGS. 6A-6J depict process steps in forming one embodiment of a raised conductive area. In FIG. 6A, a passivation layer 601 is deposited over a semiconductor die 603. The semiconductor die 603 includes a metal pad 605 and a substrate 602. The substrate can be comprised of a semi-conductive material, such as Silicon (Si), for example. Additionally, the metal pad can be comprised of Aluminum or other conductive metal. The passivation layer is composed of materials, such as silicon or silicon nitride, suitable for protecting the semiconductor die 602 from corrosion. In FIG. 6B, the passivation layer 601 is patterned to remove a portion of the passivation layer thereby forming an opening 607 over the metal pad 605. In FIG. 6C, a layer of polymide 609 is optionally deposited over the passivation layer 601. The layer of polymide 609 can be used to protect the integrated circuit (IC) from package induced stress. For example, it can be used to address planarization issued underneath the raised conductive area. The polymide layer 609 is a stress buffer and also provides isolation of the raised conductive area from other non-common areas in the presence of any cracks in the passivation layer 601. Although the polymide layer 609 is included in this example, it is to be understood that the polymide layer 609 can be omitted in other embodiments. Additionally, it is to be understood that in other embodiments, the process steps of FIGS. 6D-6J can be modified and/or implemented without the polymide layer 609.

In FIG. 6D, the polymide layer 609 is patterned to remove a portion of the polymide layer 609 thereby forming an opening 611 over the metal pad 605. It is to be understood that if the polymide layer 609 is not included, the process step of FIG. 6D can be omitted. In FIG. 6E, a seed metal layer 613, such as Titanium Tungsten (TiW) is deposited over the polymide layer 609. It is to be understood that if the polymide layer 609 is not included the seed metal layer 613 can be deposited over the passivation layer 601. In FIG. 6F, a relatively thick photoresist layer 615 is deposited over the seed metal layer 613. The thickness of the photoresist layer 615 is approximately equal to the desired total thickness of the raised conductive area being formed. For example, the photoresist layer can be formed to be about 30 μm if the total thickness of the raised conductive area is to be about 30 μm or less.

In FIG. 6G, the photoresist layer 615 is patterned to form an opening 617 that defines the width and length of the raised conductive area being formed. In FIG. 6H, a metal layer 619 is formed in the opening 619 over the seed metal layer 613. The thickness and type of material comprising the metal layer 619 is selected such that the resultant raised conductive area being formed has a hardness approximately equal to or greater than the hardness of a desired bondwire to be attached to the raised conductive area. For example, if it is desired to use a copper bondwire, the material and thickness of the metal layer 619 is selected such that the metal layer 619 has a hardness approximately equal to or greater than the hardness of the desired copper bondwire. In the example of FIG. 6, the metal layer 619 is comprised of copper and has a thickness of approximately 20 μm. However, it is to be understood that other conductive metals and/or thickness can be used in other embodiments.

Also in FIG. 6H, a metal layer 621 is formed over the metal layer 619. The metal layer 621 provides additional mechanical strength to the raised conductive area being formed. For example, in this embodiment, the metal layer 621 is comprised of Nickel and has a thickness of approximately 2 μm. However, it is to be understood that other conductive metals and/or thicknesses can be used in other embodiments. A metal layer 623 is then formed on the metal layer 621. The metal layer 623 improves the ability to bond a wire to the raised conductive area by forming an approximately oxide-free surface for formation of the stitch bond on the raised conductive area. In this example, the metal layer 623 is comprised of gold and has a thickness of approximately 0.5 μm. However, it is to be understood that other metals and/or thickness can be used in other embodiments.

Using materials such as gold or palladium for the metal layer 623 reduces the likelihood of oxidation with air. Alternatively or in conjunction with using materials such as gold or palladium, a coating of a polymer or other organic material can be used in some embodiment to also help reduce oxidation. Additionally, the surface of the metal layer 623 to which the stitch bond is attached can be smooth, rough, or patterned. For example, the roughness can be created by deposition onto or sanding the topmost surface. In another example, the surface is smooth but patterned so that there is an indication to the bonding capillary for better alignment, which helps guide the capillary.

In FIG. 6I, the photoresist layer 615 is removed which exposes portions of the seed metal layer 613 which extend beyond the metal layer 619. In FIG. 6J, the portions of the seed metal layer 613 which extend beyond the metal layer 619 are removed resulting in the raised conductive area 610. For example, a wet etch can be performed to remove the excess portions of the seed metal layer 613.

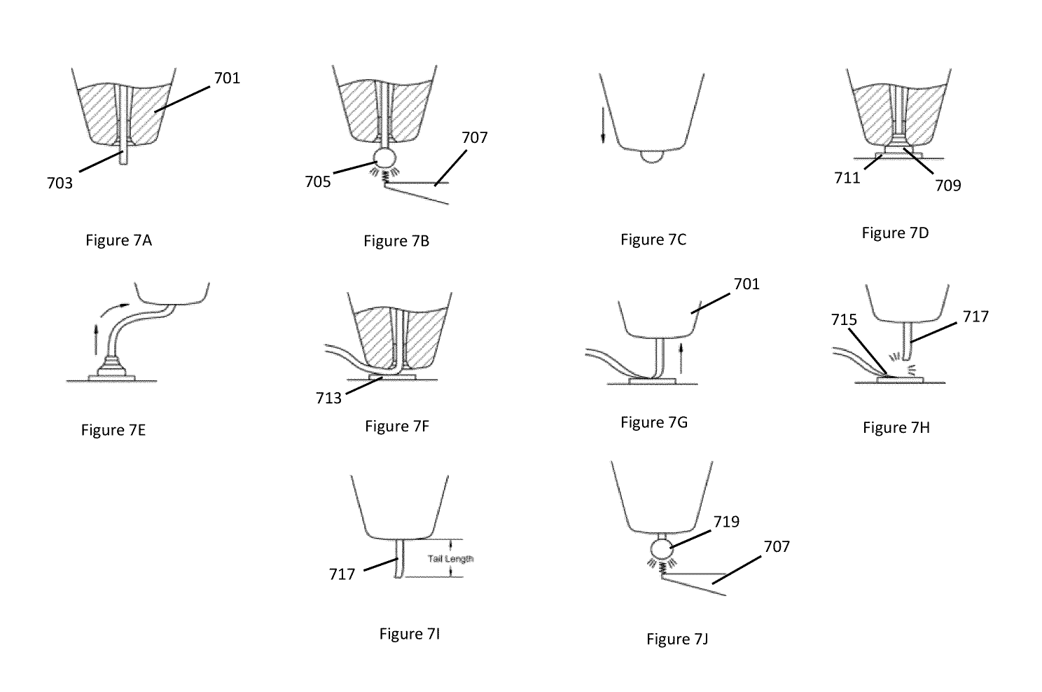

FIGS. 7A-7J depict process steps for forming a wire bond interconnect between a bond pad and a raised conductive area. For example, the process 700 depicted in FIGS. 7A-7J can be used to form the wire bond interconnect shown in FIGS. 1 and 4. The process 700 begins with a bonding capillary 701 threaded with a metal wire 703, such as a copper wire, as depicted in FIG. 7A. The capillary 701 can also be referred to as a bonder head. In FIG. 7B, a free air ball 705 is formed through Electronic Flame-Off (EFO) with an EFO electrode 707.

In FIG. 7C, the bonding capillary 701 captures the free air ball 705 in the chamfer diameter and descends to a first bond site on a bond pad such as bond pad 104 in FIG. 1. The bonding capillary 701 force and ultrasonic energy over a period of time to form the ball bond 709 on the bond pad 711 as shown in FIG. 7D. In FIG. 7E, a looping sequence is performed to loop the wire 703 to a raised conductive area, such as the exemplary raised conductive areas discussed above. In FIG. 7F, force and ultrasonic energy are applied over a period of time to a second bond site on the raised conductive area 713 to form the stitch bond on the raised conductive area 713.

In FIG. 7G, wire clamps which hold the wire 703 in place are released as the bonding capillary 701 is raised to a predetermined distance. In FIG. 7H, the wire clamps are engaged to hold the wire 703 which causes the wire 703 to break away from the stitch bond 715. By initially raising the bonding capillary 701 without releasing the wire clamps permits a portion of the wire 703 to extend below the bonding capillary 701. The extended portion 717 is often referred to as a tail 717. The tail length of the tail 717 is depicted in FIG. 7I. In FIG. 7J, another free air ball 719 is formed through EFO with the EFO electrode 707 in preparation for forming another wire bond interconnect.

Thus, the process 700 provides a wire bond interconnect between a bond pad and a raised conductive area with a single Electronic Flame-Off. In addition, since separate ball bonds do not have to be formed at each bond site, the risk of oxidation of the bond is reduced. In particular, rather than forming a ball bond at each bond site and then bonding the wire to each ball bond, the ball bond to the wire is formed and then a stitch bond is formed directly to the second bond site. That is, a pre-preparation stage of placing balls at each of the different bond sites and then returning to the prepared balls for final wire bonding is avoided. Thus, the risk of oxidation of the is reduced since the bonding material is exposed to the environment for less time before forming the bond. This is beneficial in forming copper bonds since copper oxidizes more readily than other materials such as gold.

In addition, the reliability of the bonds is improved since the bonding capillary does not need to return to the previous site of a ball bond to then form the bond to the wire. In particular, the risk of misalignment between the ball bond and the wire on the first bond site is reduced. Additionally, concerns of misalignment and/or bonding the stitch bond to a non-uniform ball bond are alleviated since there is no ball bond between the stitch bond and the raised conductive area.

Another advantage provided by the process 700 is that less pressure is applied to the bonding sites than in conventional techniques. In particular, in a process which first forms a ball bond and then returns to bond the wire to the ball bond, pressure is applied to the bond site twice. In the process 700, however, pressure from the bonding capillary is only applied once to each bond site. Furthermore, the use of a raised conductive area as described above improves bond integrity by forming the stitch bond on a nearly oxide free surface that has approximately uniform shape and hardness. Additionally, the stitch bond is formed entirely on the surface of the raised conductive area rather than a ball bond which improves thermal transfer and current carrying capacity. Importantly, the embodiments described above enable the direct coupling of copper wire to the raised conductive area including the use of copper wire having a diameter greater than 0.9 mil. The use of thicker bondwire is beneficial in applications using high currents which need thicker bondwires, for example. Conventional bonding techniques typically require the use of a ball bond between a stitch bond and the bond pad and do not support the bonding of copper wires greater than 0.9 mil. Hence, the systems and methods described herein provide advantages over the conventional bonding techniques.

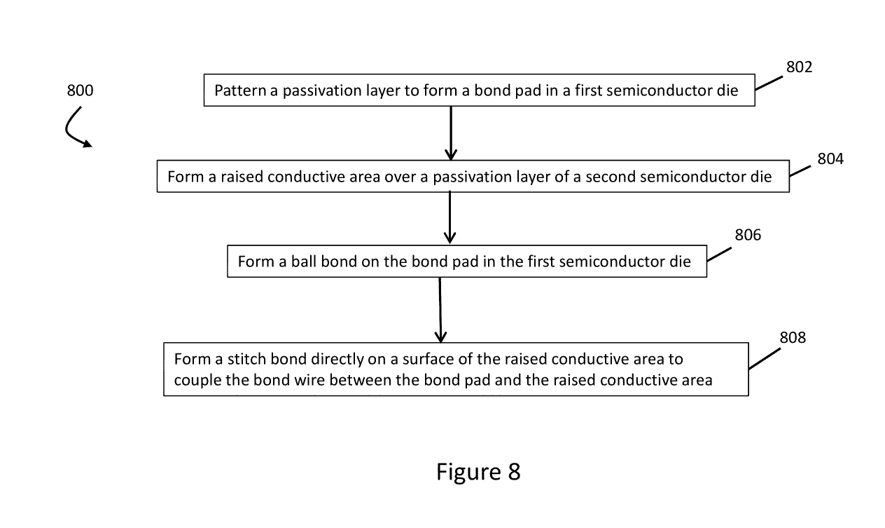

FIG. 8 is a flow chart of one embodiment of a method 800 of forming a semiconductor package. At block 802, a passivation layer is patterned to form a bond pad in a first semiconductor die. At block 804, a raised conductive area is formed over a passivation layer of a second semiconductor die. For example, the process steps described in FIGS. 6A-6J are used in some embodiments, to form the raised conductive area. At block 806, a ball bond is formed on the bond pad in the first semiconductor die. At block 808, a stitch bond is formed directly on a surface of the raised conductive area to couple the bond wire between the bond pad and the raised conductive area.

Hence, as described above, the embodiments described herein enable multiple benefits for wire bonding interconnects. For example, the embodiments described herein enable the implementation of thicker copper wire (e.g. greater than 0.9 mil) for die to die copper wire bonds. Indeed, in one embodiment a copper diameter of 1.3 mil is used and in other embodiments a diameter of greater than 1.3 mil can be used. For example, in some embodiments implementing power devices, a copper wire having a diameter of 2 to 3 mil can be used. The embodiments described herein also improve efficiency by reducing the number of process steps. For example, the embodiments described herein reduce the number of EFOs and enable a single stitch bond versus two bonds on a conventional bond pad (e.g. a stitch bond on a ball bond). Additionally, the embodiments described herein enable standardization to the ball bonder which streamlines operations and assembly house floor space.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A semiconductor package comprising:
a bond pad formed on a first semiconductor die, a surface of the bond pad exposed through an opening in a passivation layer on the first semiconductor die;
a raised conductive area formed on top of a passivation layer on a second semiconductor die; and
a bond wire having a first end coupled to the bond pad via a ball bond and a second end coupled directly to a surface of the raised conductive area via a stitch bond;
wherein the raised conductive area is comprised of a plurality of metal layers, each of the metal layers comprised of a respective material and having a respective thickness;
wherein the thickness and material of at least one of the plurality of metal layers is selected such that a hardness of the raised conductive area is at least as hard as a hardness of the bond wire.

2. The semiconductor package of claim 1, wherein the bond wire is comprised of copper.

3. The semiconductor package of claim 2, wherein the copper bond wire has a diameter greater than 0.9 mil.

4. The semiconductor package of claim 3, wherein the copper bond wire has a diameter between approximately 2 mil to 3 mil.

5. The semiconductor package of claim 1, wherein the raised conductive area comprises:
a seed metal layer, at least a portion of the seed metal layer overlying the passivation layer of the second semiconductor die;
a first metal layer overlying the seed metal layer;
a second metal layer overlying the first metal layer; and
a third metal layer overlying the second metal layer, the stitch bond formed on a surface of the third metal layer;
wherein the first metal layer is relatively thicker than the seed metal layer, the second metal layer and the third metal layer.

6. The semiconductor package of claim 5, wherein the first metal layer is comprised of copper.

7. The semiconductor package of claim 5, wherein the first metal layer has a thickness of approximately 20 μm.

8. The semiconductor package of claim 1, wherein a portion of the seed metal layer overlies and is electrically coupled to a bond pad through an opening in the passivation layer of the second semiconductor die.

9. The semiconductor package of claim 1, further comprising a second bond wire having an end coupled directly to a surface of the raised conductive area via a second stitch bond.

10. A method of forming a semiconductor package, the method comprising:
patterning a passivation layer to form a bond pad in a first semiconductor die;
forming a raised conductive area over a passivation layer of a second semiconductor die; and
forming a ball bond on the bond pad in the first semiconductor die and a stitch bond directly on a surface of the raised conductive area to couple a bond wire between the bond pad and the raised conductive area.

11. The method of claim 10, wherein forming the raised conductive area comprises:
forming a seed metal layer over the passivation layer and the surface of the metal pad;
forming a first metal layer over the seed metal layer;
forming a second metal layer over the first metal layer; and
forming a third metal layer over the second metal layer;
wherein the stitch bond is formed directly on a surface of the third metal layer.

12. The method of claim 11, wherein forming the first metal layer comprises forming the first metal layer to have a thickness such that a hardness of the first metal layer is approximately equal to a hardness of the bond wire.

13. The method of claim 11, wherein forming the raised conductive area further comprises forming a polymide layer between the passivation layer and the seed metal layer.

14. The method of claim 11, wherein forming the raised conductive area further comprises patterning a passivation layer to expose a surface of a metal pad in the second semiconductor die; and
wherein forming the seed metal layer comprises forming the seed metal layer over the passivation layer and the exposed surface of the metal pad.

15. The method of claim 11, wherein forming the first metal layer comprises forming the first metal layer of copper;
wherein forming the second metal layer comprises forming the second metal layer of nickel; and
wherein forming the third metal layer comprises forming the third metal layer of gold.

16. The method of claim 10, wherein forming a ball bond on the first semiconductor die comprises forming a copper ball bond on the bond pad; and
wherein forming the stitch bond comprises forming a copper stitch bond directly on the surface of the raised conductive area.

17. A method of forming a bond wire interconnect, the method comprising:
forming a ball bond to attach a first end of a bond wire to a bond pad;
looping the bond wire to a raised conductive area disposed on top of a passivation layer without breaking the bond wire after forming the ball bond; and
forming a stitch bond directly on a surface of the raised conductive area to couple a second end of the bond wire directly to the surface of the raised conductive area.

18. The method of claim 17, wherein forming the ball bond comprises forming the ball bond to attach a first end of the bond wire to the bond pad on a first semiconductor die; and
wherein forming the stitch bond comprises forming the stitch bond directly on the surface of the raised conductive area on a second semiconductor die.

19. The method of claim 17, wherein forming the ball bond comprises:
threading a bonding capillary with the bond wire;
producing a free air ball at an end of the bond wire with an Electronic Flame-Off electrode;
placing the free air all on the bond pad; and
applying pressure and ultrasonic energy to produce the ball bond on the bond pad;
wherein the stitch bond is formed directly on the surface of the raised conductive pad such that a single Electronic Flame-Off is performed in forming the bond wire interconnect;

20. The method of claim 19, wherein forming the stitch bond comprises:
placing the bond wire in direct contact with the surface of the raised conductive area;
applying pressure and ultrasonic energy with the bonding capillary to produce the stitch bond on the raised conductive area;
the method further comprising:
lifting the bonding capillary from the surface of the raised conductive area without clamping the bond wire to produce a bond wire tail; and
producing a second free air ball at an end of the bond wire tail with the Electronic Flame-Off electrode, the second free air ball used in forming a ball bond on a bond pad in a second bond wire interconnect.
